(19) United States
(12) Patent Application Publication
(10) Pub. No.: US 2022/0052008 A1
(43) Pub. Date: Feb. 17, 2022

(54) Semiconductor Device, Method Making It And Packaging Structure

(71) Applicant: ChangXin Memory Technologies, Inc., Hefei City (CN)

(72) Inventor: Zengyan Fan, Hefei City (CN)

(21) Appl. No.: 17/430,895

(22) PCT Filed: Jun. 19, 2020
(86) PCT No.: PCT/CN2020/097117

§ 371 Date: Aug. 13, 2021

(30) Foreign Application Priority Data
Nov. 7, 2019 (CN) 201911080689.2

(51) Int. Cl. H01L 23/00

(52) U.S. Cl. CPC H01L 24/14; H01L 24/02; H01L 24/05; H01L 24/13; H01L 24/03; H01L 24/11; H01L 2924/3511; H01L 2224/02373; H01L 2224/0401; H01L 2224/05008; H01L 2224/13026; H01L 2224/11462; H01L 2224/14517; H01L 2224/02311

(57) ABSTRACT

The disclosure relates to a semiconductor structure, including: a substrate, a bonding pad, a first protective layer, a redistribution layer, a connecting plug, bumps, and a second protective layer. The redistribution layer includes a first metal line and a second metal line. Since the second metal line and the first metal line are of the same height, so the bumps on the first metal line and the second metal line are equivalently formed on the same layer. The coplanarity of the bumps on the metal lines is relatively high. The second metal line does not make any electrical connection to the pad so the bumps formed on the second metal line do not play a conductive role. When the substrate warps, the stress is transferred to the first protective layer. Thus, bumps in the substrate made according to the present application are coplanar, which reduces the probability of poor wetting when flip-chip package on the substrate, and improves the reliability of the entire package.

### CROSS REFERENCES TO RELATED APPLICATIONS

This application claims the benefit of priority to CN Patent Application CN 201911080689.2 filed on Nov. 7/2019, both entitled “SEMICONDUCTOR DEVICE, METHOD MAKING IT AND PACKAGING STRUCTURE”, the contents of which are incorporated herein by reference in its entirety.

### TECHNICAL FIELD

The invention relates to the field of semiconductor packaging, in particular, to a semiconductor structure, a fabrication method, and a semiconductor packaging structure.

### BACKGROUND

The flip-chip packaging technology is an interconnection method for applications of small size chips, high I/O density, and excellent electrical and thermal performance. Solder balls or bumps are prepared on the chip pads and then packaged on the circuit board.

With the current techniques, to even out the stress problems generated during packaging, bumps or solder balls are usually also applied at positions where there are no pads. However, bumps or solder balls located at positions where there are no pads are different from those put where there are pads, so the bumps or solder balls on or not on pads are not coplanar, which leads to poor wetting when flip-chip is packaged on the substrate, thus affecting the reliability of the entire package.

### SUMMARY

Therefore it is necessary to provide a semiconductor structure, a manufacturing method, and a semiconductor packaging structure to solve the bump's poor coplanarity problem.

According to one embodiment of the disclosure, the semiconductor structure includes: a substrate; a pad disposed on the substrate; a first protective layer disposed on a part of the pad; a connection plug, which is disposed in the first protective layer; and a rewiring layer disposed on the first protective layer; the rewiring layer includes a first metal line and a second metal line; the first metal line is electrically connected to the pad via the connection plug; the second metal line is flush with the upper surface of the first metal line, and the second metal line is not electrically connected.

The second protective layer is disposed on the upper surface of the first protective layer and covers the redistribution layer; a first opening and a second opening are formed in the second protective layer, and the first opening exposes the first metal line, and the second opening exposes the second metal line.

Bumps are disposed on the upper surface of the first metal line and the second metal line.

Through the above technical solution, since the second metal line and the first metal line have the same height, the bumps on the first metal line and the bumps on the second metal line are formed on the same layer, so the chance of the bumps on the first metal line and the bumps on the second metal line will be coplanar is relatively high. The second metal line is insulated from the pad, therefore, the bump formed on the second metal line does not conduct, which transfers the stress to the first protective layer when the substrate warps. With this technique in the present application, the bumps in the substrate have better coplanarity, which reduces the probability of poor wetting during flip-chip package on the substrate, and improves the reliability of the entire package.

In one of the embodiments, the structure further includes an under-bump metal layer, the under-bump metal layer is dispose on the inner surfaces of the first opening and the second opening, and is in contact with the bumps and both the first metal line and the second metal line.

Through the above technical solution, the bonding force between the first and second bumps and the first and second metal lines under the first and second bumps is higher respectively. The structure is more stable and reliable than if the bumps are directly disposed on the sidewalls of the first opening and the second opening.

In one of the embodiments, there is a distance between the second metal line and the first metal line.

In one of the embodiments, the width of the second opening is smaller than the width of the second metal line, and the distance between the edge of the second opening and the edge of the second metal line is 2.5 um-7 um.

In one of the embodiments, the redistribution layer further includes a plurality of plugs, and the plugs penetrate the first protection layer along the thickness direction of the first protection layer; the first metal line and the second metal line are respectively connected to different plugs, and the widths of the first metal line and the second metal line are both larger than the widths of the plugs.

In one of the embodiments, the first protective layer includes a polymer layer and a passivation layer, the passivation layer is disposed on the upper surface of the substrate, and the polymer layer is located on the upper surface of the passivation layer.

In one of the embodiments, a method for manufacturing a semiconductor structure is also provided, which includes the following steps: providing a substrate, and forming a pad on the substrate; forming a first protective layer on the substrate to cover part of the pad; forming a connection plug in the first protection layer, and forming a redistribution layer on the upper surface of the first protection layer.

The redistribution layer includes a first metal line and a second metal line. The first metal line is electrically connected to the pad via the connection plug; the second metal line is flush with the upper surface of the first metal line, and the second metal line is not electrically connected.

The method further comprises forming a second protective layer on the upper surface of the first protective layer; forming a first opening and a second opening in the second protective layer, the first opening exposes the first metal line, and the second opening exposes the second metal line; forming bumps on the upper surfaces of the first metal line and the second metal line.

In the above technical solution, the second metal line and the first metal line arc of the same height, so the bumps on the first metal line and the bumps on the second metal line are equivalently formed on the same layer, so the bumps on the first metal line and the bumps on the second metal line are relatively high in coplanarity. The second metal line is insulated from the pad so the bump formed on the second metal line does not conduct. When the substrate warps, the stress is transferred to the first protective layer. Thus, bumps in the substrate of the present application have better coplanarity, which reduces the probability of poor wetting during flip-chip package on the substrate, and improves the reliability of the entire package.

In one of the embodiments, after providing the chip including the pad, the method further includes: forming a first protective layer on the substrate includes: forming a passivation layer on the upper surface of the substrate; and forming a polymer layer on the passivation layer.

In one of the embodiments, the width of the second opening is smaller than the width of the second metal line, and the distance between the edge of the second opening and the edge of the second metal line is 2.5 um-7 um.

In one of the embodiments, after forming the first opening and the second opening in the second protective layer, and before forming the bump, the method further includes the following steps: forming an under-bump metal layer on the inner surfaces of the first opening and the second opening, and the under-bump metal layer is in contact with both the first metal line and the second metal line; The bump is formed on the surface of the metal layer under the bump.

In one of the embodiments, forming a connection plug in the first protective layer and forming the rewiring layer on the upper surface of the first protective layer includes the following steps:

forming a connection opening in the first protection layer, and the connection opening exposes the pad; forming the connection plug in the connection opening.

The first metal line and the second metal line are formed on the upper surface of the first protective layer; the first metal line is connected with the connection plug.

In one of the embodiments, the redistribution layer further includes several plugs; forming connection plugs in the first protection layer and forming the redistribution layer on the upper surface of the first protection layer includes the following steps: forming a connection opening and a through opening in the first protective layer, and the connection opening exposes the pad; forming the connecting plug in the connecting opening, and forming the plug in the through opening.

The first metal line and the second metal line are formed on the upper surface of the first protective layer; the first metal line is connected to the connecting plug and part of the plug; the second metal line is connected with the remaining plugs, and the width of the first metal line and the width of the second metal line are both larger than the width of all the plugs.

In one of the embodiments, a semiconductor package structure is also provided, and the semiconductor package structure includes the above-mentioned semiconductor structure.

In one of the embodiments, the semiconductor structure is flip-chip package on a substrate, the bumps are attached to the substrate, a plastic encapsulation layer is formed on the periphery of the semiconductor structure, and the plastic encapsulation layer wraps the bumps.

It should be understood that the above general description and the following detailed description arc only exemplary and cannot limit the present disclosure.

### BRIEF DESCRIPTION OF THE DRAWINGS

By describing its exemplary embodiments in detail with reference to the accompanying drawings, the above and other objectives, features and advantages of the present disclosure will become more apparent.

FIG. 1 is a schematic structural diagram showing a semiconductor structure in an embodiment of the present invention;

FIG. 2 is a schematic structural diagram showing a semiconductor structure according to another embodiment of the present invention;

FIG. 3 is a schematic diagram showing the structure of a semiconductor package structure according to an embodiment of the present invention;

FIG. 4 is a flowchart of a method for manufacturing a semiconductor structure in an embodiment of the present invention;

FIGS. 5 to 11 are schematic diagrams showing the structures of each step in the method for manufacturing a semiconductor structure according to an embodiment of the present invention;

FIGS. 12-14 are schematic diagrams showing the structures of each step in the method for fabricating a semiconductor structure according to another embodiment of the present invention.

### DETAILED DESCRIPTION OF THE PREFERRED EMBODIMENTS

In order to facilitate the understanding of the present invention, the present invention will be described more fully below with reference to the relevant drawings. The preferred embodiments of the present invention are shown in the drawings. However, the present invention can be implemented in many different forms and is not limited to the embodiments described herein. On the contrary, the purpose of providing these embodiments is to make the disclosure of the present invention more thorough and comprehensive.

Unless otherwise defined, all technical and scientific terms used herein have the same meaning as commonly understood by those skilled in the technical field of the present invention. The terms used in the description of the present invention herein are only for the purpose of describing specific embodiments, and are not intended to limit the present invention. The term “and/or” as used herein includes any and all combinations of one or more related listed items.

In the description of the present invention, it should be understood that the orientation or positional relationship indicated by the terms “upper”, “lower”, “vertical”, “horizontal”, “inner”, and “outer” are based on the figures shown in the drawings. The method or position relationship is only for the convenience of describing the present invention and simplifying the description, rather than indicating or implying that the device or element referred to must have a specific orientation, be constructed and operated in a specific orientation, and therefore cannot be understood as a limitation of the present invention.

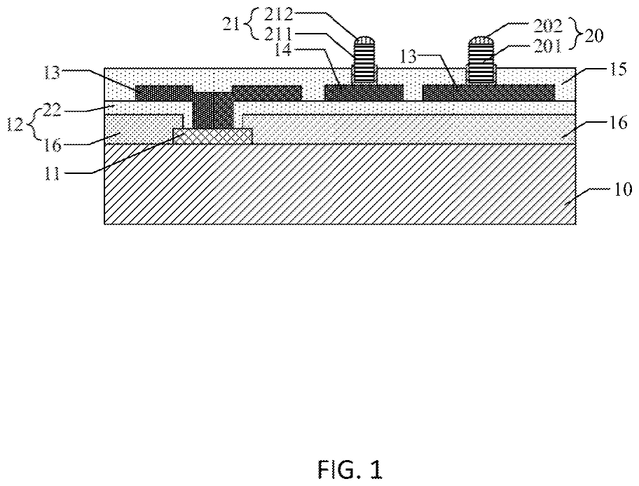

As shown in FIG. 1, an embodiment of the present application provides a semiconductor structure, a substrate 10, and a chip is formed in the substrate 10 (not shown in the drawings);

The pad 11 is disposed on the substrate 10 and is electrically connected to the chip;

The first protective layer 12 is disposed on the substrate 10 and covers a part of the pad 11;

The connection plug is formed in the first protective layer 12;

The redistribution layer is disposed on the first protective layer 12; the redistribution layer includes a first metal line 13 and a second metal line 14; the first metal line 13 is electrically connected to the pad 11 through a connection plug; the second metal line 14 is flush to the upper surface of the first metal line 13, and the second metal line 14 is not electrically connected.

The second protective layer 15 is disposed on the upper surface of the first protective layer 12 and covers the redistribution layer; a first opening and a second opening are formed in the second protective layer 15, and the first opening exposes the first metal line 13, and the second openings exposes the second metal line 14;

A bump 20 is formed on the upper surface of the first metal line 13, and a bump 21 is formed on the upper surface of the second metal line 14.

Specifically, in an optional embodiment, the substrate may be a bulk silicon substrate, a silicon-on-insulator substrate, or other semiconductor materials including group III, group IV, and group V semiconductors, and the pad 11 is a metal, which may compose of aluminum or aluminum alloy, and the pad 11 is electrically connected to the chip in the substrate 10.

The first protective layer 12 includes a polymer layer 22 and a passivation layer 16. The polymer layer 22 is formed on the upper surface of the substrate 10, and is made of a certain elastic and insulating polymer, and may be a polyimide. In other embodiments, the polymer layer 22 may also be made of epoxy resin, benzene, etc. And the formation of cyclobutene or polybenzoxazole. The thickness of the polymer layer 22 is between 3-7 um, and may be 5 um. The passivation layer 16 is formed on the outer surface of the polymer layer 22 and wraps the edges of the pad 11.

The first metal line 13 and the second metal line 14 are formed simultaneously, so the two have the same height. The first metal line 13 and the second metal line 14 may be composed of aluminum. The first metal line 13 is removed from the first protective layer through a connecting plug. The opening on structure 12 at the pad 11 is in contact with the pad 11 so there is electrical connection between the first metal line 13 and the pad 11. In addition to the pad 11 and the first metal line 13 in the semiconductor structure, there may be other conductive structures such as pads or lines, and the second metal line 14 is insulated from all conductive structures in the semiconductor structure.

The bump 20 includes a metal bump 201 and a solder layer 202. The metal bump 201 is electrically connected to the pad 11 through the first metal line 13. The metal bump 201 may be composed of copper, and the solder layer 202 is formed on the side of the metal bump 201 away from the first metal line 13, the solder layer 202 may be composed of tin or tin-silver alloy or the like.

A bump 21 is prepared on the second metal line 14. The bump 21 includes a metal bump 211 and a solder layer 212. The metal bump 211 may be composed of copper. The solder layer 212 is formed on the side of the metal bump 211 away from the first metal line 14. The solder layer 212 is composed of tin or tin-silver alloy. Since the second metal line 14 is insulated from the pad 11, the bump 21 is also insulated from the pad 11, and the bond between the metal bump and the metal solder layer is more stable and reliable, no bump drift will occur.

The height of the metal bump 201 and the height of the metal bump 211 are the same at between 25-40 μm, which can be 30 μm, the height of the solder layer 202 and the height of the solder layer 212 are the same at between 15-30 um, which can be 20 um. The height of the bump 20 and the height of the bump 21 arc the same at about 50 um. Since the second metal line 14 is formed on the first protective layer 12, the stress that it bears can be transferred to the polymer layer 22. Since the second metal line 14 and the first metal line 13 are of the same height, the bump 20 and the bump 21 are equally high because they are formed on the same layer, so that the bump 20 and the bump 21 are coplanar, and the probability of poor wetting on the substrate at flip-chip can be reduced, thus improving the reliability of the entire package.

In other optional embodiments, there is a buffer gap between the second metal line 14 and the first metal line 13, and the second metal line 14 does not directly contact the first metal line 13 physically, so the second metal line 14 can have large area for transferring larger stress with the larger space.

The material of the second protective layer 15 may be the same as that of the polymer layer 22. The first metal line 13 and the second metal line 14 are located between the polymer layer 22 and the second protective layer 15, so that the first metal line 13 and the second metal line The thread 14 is not easy to fall off from the polymer layer 22, and is more stable and firm.

In an alternative embodiment, the second protective layer 15 is provided with a first opening at the first metal line 13, and the second protective layer 15 is provided with a second opening at the second metal line 14. The inner surfaces of both the first opening and the second opening are sputtered with under-bump metal layers 17, and the bumps 20 and 21 arc both grown on the under-bump metal layer 17, so that the bump 20 and the bump 21 arc connected to the first opening and the second opening respectively. The inner walls can be effectively adhered to the bumps with a higher bonding force, the adhesion is more reliable than growing the metal bumps directly on the second protective layer 15.

The width of the second opening is smaller than the width of the second metal line 14, and the distance between the edge of the second opening and the edge of the second metal line 14 is 2.5 um-7 um, this distance helps with setting the size of the second opening.

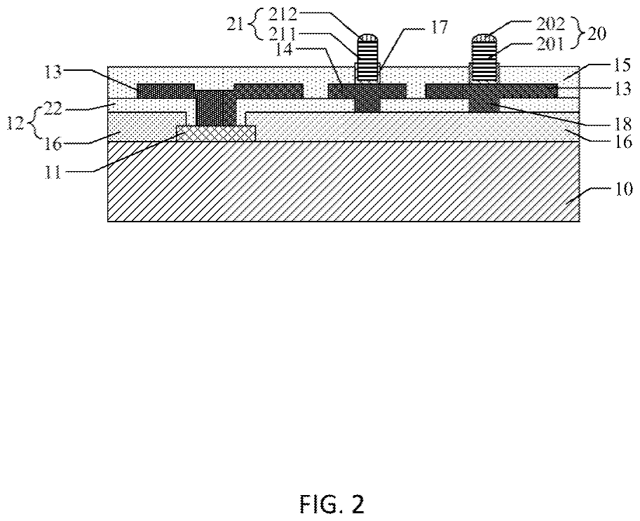

As shown in FIG. 2, in other optional embodiments, the polymer layer 22 is provided with a connecting trench, a plug 18 is grown in the connecting trench, and the first metal line 13 is integrated and connected with the plug 18, and the second metal line 14 is integrated and connected with the plug 18, so that the connections between the first metal line 13, the second metal line 14 and the polymer layer 22 are more stable and reliable, less likely to fall off.

The cross section of the plug 18 is smaller than the cross section of the second metal line 14, so when the bump 21 on the second metal line 14 is stressed, the stress can be better transferred to the polymer layer 22.

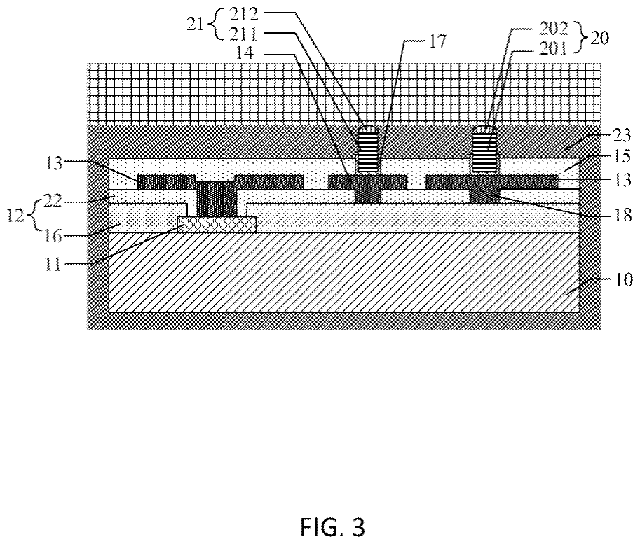

As shown in FIG. 3, in an optional embodiment, the present disclosure also provides a semiconductor package structure which includes the above-mentioned semiconductor structure. Specifically, the semiconductor structure is bonded to the substrate. A plastic encapsulation layer 23 is formed on the periphery of the structure, and the plastic encapsulation layer 23 may be made of epoxy resin. The plastic encapsulation layer 23 surrounds the metal bump 201 and the metal bump 211, and the solder layer 212 and the solder layer 202 pass through the encapsulation layer 23 and are bonded to the substrate by the interconnecting parts. The plastic encapsulation layer 23 can protect the bump 20 and the bump 21, and at the same time prevent the semiconductor structure from falling off the substrate.

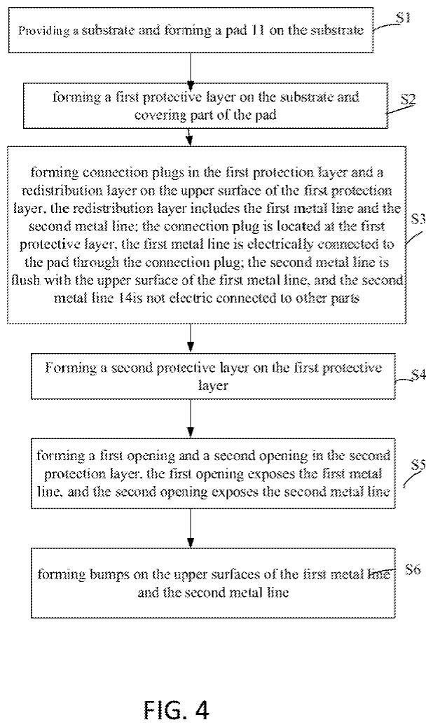

As shown in FIG. 4, according to an optional embodiment, a method for manufacturing the semiconductor structure is also provided, which includes the following steps:

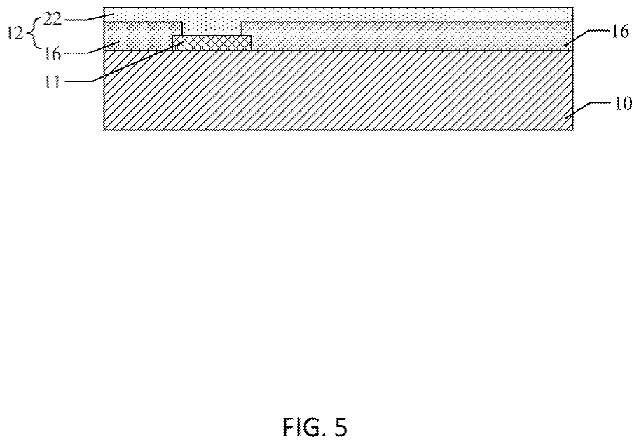

Step S1: A substrate 10 is provided, and a pad 11 is formed on the substrate 10, as shown in FIG. 5.

Specifically, a chip (not shown) is formed in the substrate 10, and the pad 11 is electrically connected to the chip. In an optional embodiment, step S1 specifically includes:

Step S101: cleaning the surface of the substrate 10 to remove surface particles and organic matters;

Step S102: forming a plurality of pads 11 on the substrate 10, so that the pads 11 are electrically connected to the chips in the substrate 10.

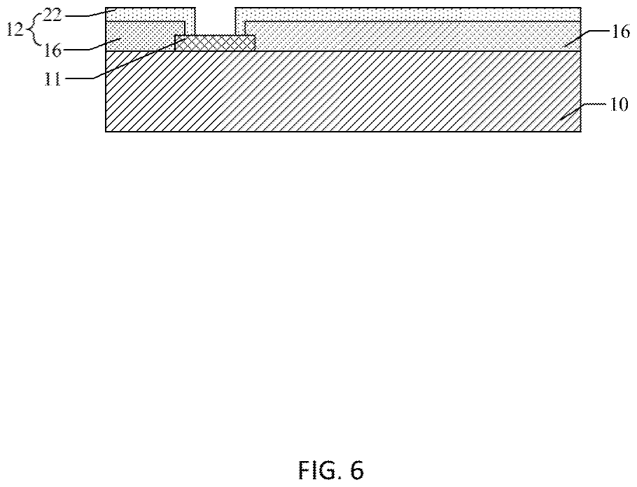

Step S2: forming a first protective layer 12 on the substrate 10, as shown in FIGS. 5-6.

Step S2 specifically includes:

Step S201: forming a passivation layer 16 on the substrate 10, and the passivation layer 16 surrounds the edges of the pads 11;

Step S202: forming a polymer layer 22 on the upper surface of the passivation layer 16.

Specifically, the thickness of the polymer layer 22 is between 3-7 um and may be 5 um for example. The polymer layer 22 is made of a certain elastic and insulating polymer, and may be a polyimide layer. In other embodiments, the polymer layer 22 may also be formed of epoxy resin, benzocyclobutene, polybenzoxazole, or the like.

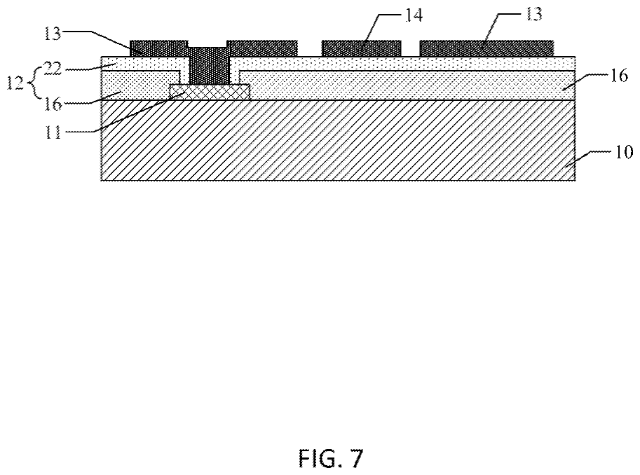

Step S3: forming connection plugs in the first protection layer 12, and forming a redistribution layer on the upper surface of the first protection layer 12. The redistribution layer includes the first metal line 13 and the second metal line 14; the connection plug is located at the first protective layer 12, the first metal line 13 is electrically connected to the pad II through the connection plug; the second metal line 14 is flush with the upper surface of the first metal line 13, and the second metal line 14 does not have electric connection to other parts, as shown in FIGS. 6-7.

The step S3 includes the following specific steps:

Step S301: forming a connection opening in the first protection layer 12, and the connection opening exposes the pad, as shown in FIG. 6;

Step S302: forming a connecting plug in the connecting opening, as shown in FIG. 7:

Step S303: The first metal line 13 and the second metal line 14 are formed on the upper surface of the first protective layer 12 by electroplating, and the first metal line 13 is connected to the connecting plug, as shown in FIG. 7.

In this embodiment, the first metal line 13 and the second metal line 14 may be formed of metal copper, the second metal line 14 is not in contact with the first metal line 13, and there is a buffer space between the two.

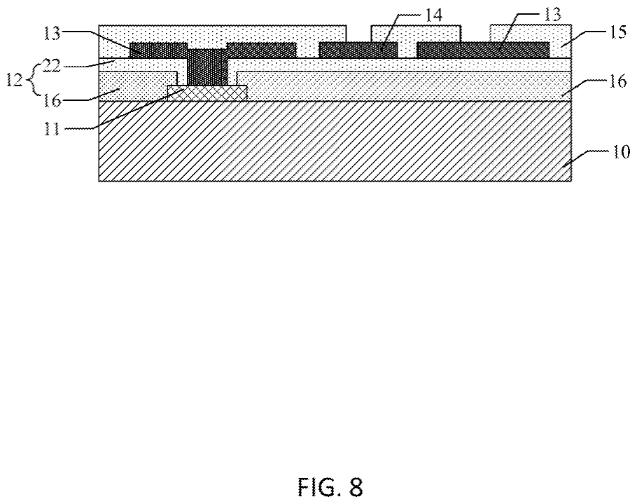

Step S4: forming a second protective layer 15 on the upper surface of the first protective layer 12, as shown in FIG. 8;

Step S5: forming a first opening and a second opening in the second protection layer 15, the first opening exposes the first metal line 13, and the second opening exposes the second metal line 14.

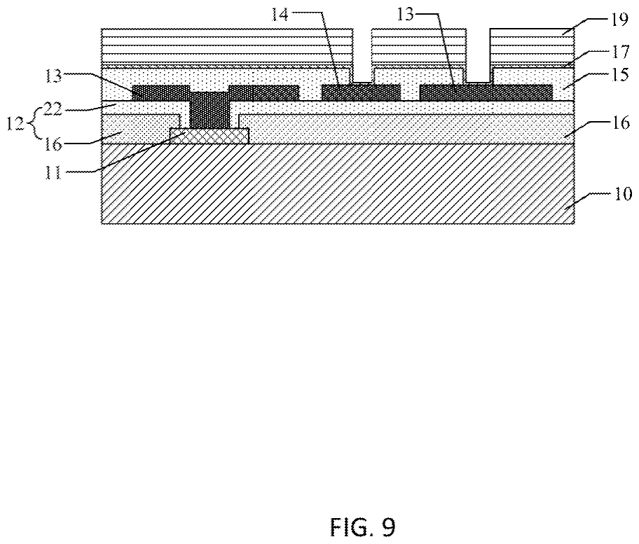

Specifically, as shown in FIGS. 8-9, in an optional embodiment, step S5 includes:

Step S501: opening the first opening and the second opening on the second protective layer 15 by lithographical exposure and development, as shown in FIG. 8;

Step S502: forming an under-bump metal layer 17 on the second protective layer 15 and the inner surface of the first opening and the inner surface of the second opening by sputtering, as shown in FIG. 9;

Step S503: coating the photoresist layer 19 on the under-bump metal layer 17, and open the first opening and the second opening in the photoresist layer 19 through exposure and development, as shown in FIG. 9.

In this embodiment, the width of the second opening is smaller than the width of the second metal line 13, the distance between the edge of the second opening and the edge of the second metal line 13 is 2.5 um-7 um, and the inner surface of the first opening includes the side walls and the bottom wall of the first opening, the inner surface of the second opening includes the side walls and the bottom wall of the second opening, and the thickness of the photoresist layer 19 is 50-60 um, which may be 55 um for example.

Step S6: forming bump 20 on the upper surface of the first metal line 13 and forming bump 21 on the upper surface of the second metal line 14.

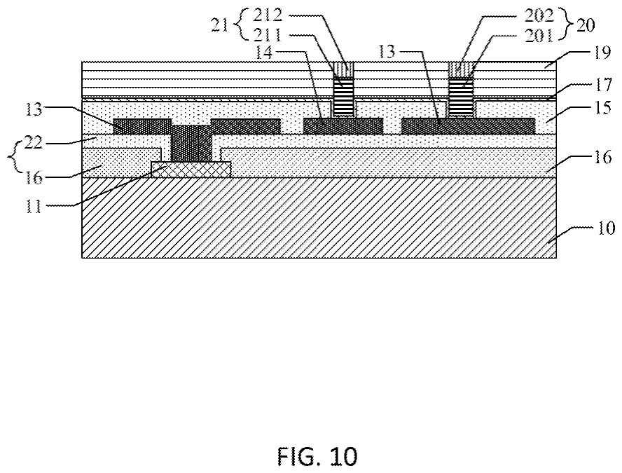

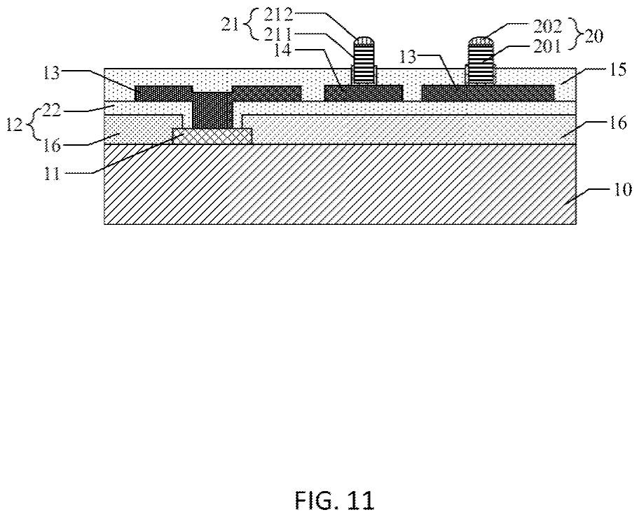

Specifically, as shown in FIGS. 10-11, in an optional embodiment, step S6 includes the following steps:

Step S601: electroplating metal bump 201 and metal bumps 211 in the first opening and the second opening, forming a solder layer 202 on the metal bump 201, and forming a solder layer 212 on the metal bump 211, as shown in FIG. 10;

Step S602: removing the photoresist layer 19, and etching the under-bump metal layer 17 sputtered on the second protective layer 15, as shown in FIG. 11;

Step S603: reflowing the solder layer 202 and the solder layer 212 so they form hemispherical shapes, as shown in FIG. 11.

In this embodiment, the thickness of the second protection layer 15 is between 3-7 um, which can be 5 um for example, the metal bump 201 and the metal bump 211 can be composed of copper, and the solder layer 202 and the solder layer 212 can be composed of tin or tin silver alloy etc. The heights of the metal bump 201 and the metal bump 211 arc the same and between 25-40 um, which can be 30 um for example, the heights of the solder layer 202 and the solder layer 212 are the same and between 15-30 um, which can be 20 um for example, the heights of the bump 20 and the bump 21 are the same and can be 50 um for example.

Since the second metal line 14 and the first metal line 13 are of the same height, the bump 20 and the bump 21 are equivalently formed on the same layer, so the bump 20 and the bump 21 are relatively coplanar. This technique can eliminate the adverse effect of the bumps 20 and 21 not being coplanar on the first and second protective layer 15. When the thickness of the second protective layer 15 is 5 um and the heights of the bumps 20 and 21 are 50 um, the coplanarity can be improved by 10%. When the chip is flip-chip package on the substrate, the probability of poor wetting is reduced, which improves the reliability of the entire package.

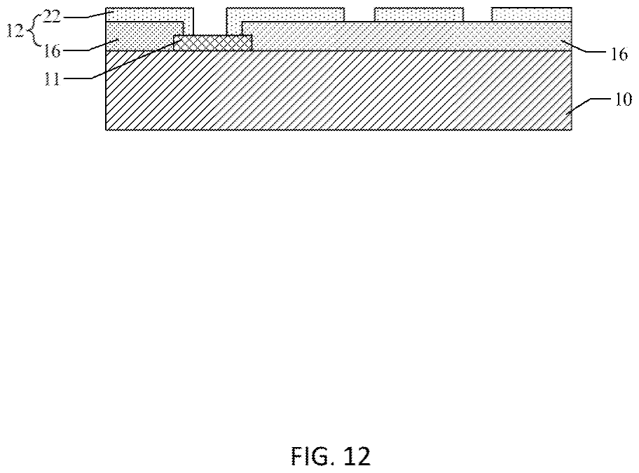

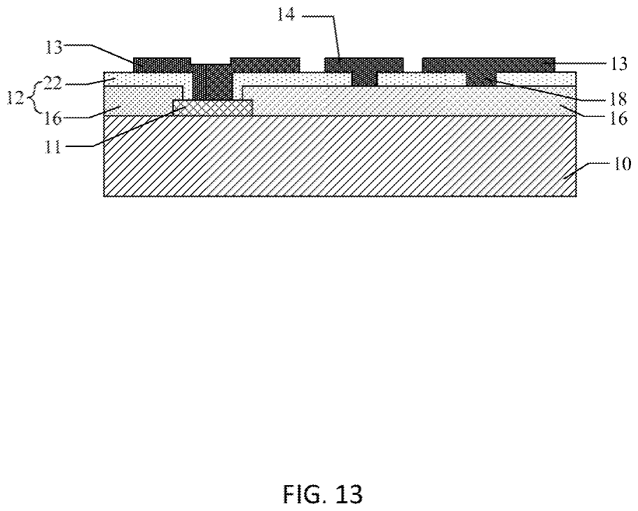

As shown in FIGS. 12-13, in other optional embodiments, step S3 specifically includes the following steps:

Step S301: forming a connection opening and a through opening in the first protective layer 12, and the connection opening exposes the pad 11, as shown in FIG. 12;

Step S302: forming a connecting plug in the connecting opening, and forming a plug 18 in the through opening, as shown in FIG. 13;

Step S303: forming a first metal line 13 and a second metal line 14 on the upper surface of the first protective layer 12; the first metal line 13 is connected to the connecting plug and part of the first plug 18, the first plug 18 is connected; the second metal line 14 is connected to the remaining plug. The lateral width of the first metal line 13 and the lateral width of the second metal line 14 are both larger than the width of the first plug 18, as shown in FIG. 13.

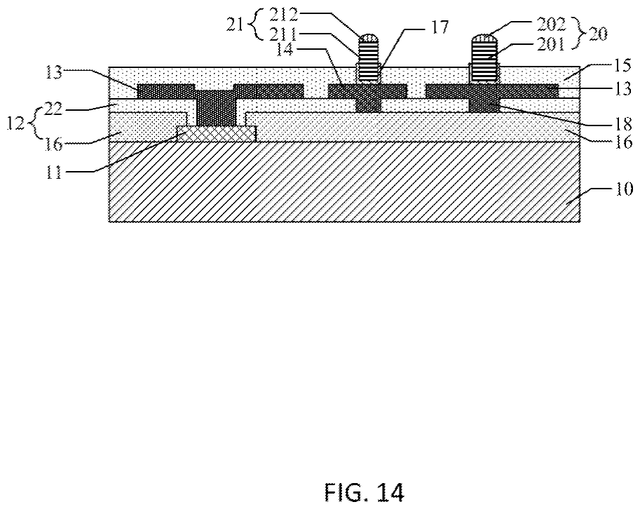

In this embodiment, through the same steps as the other embodiments, a semiconductor package structure with a first plug 18 as shown in FIG. 14 is prepared. The first plug 18 between the first protective layer 12 and each of the first metal line 13 and the second metal line 14 more stable and reliable, so not easy to fall off. The cross section of the first plug 18 is smaller than the cross section of the second metal line 14, so when the bump 21 over the second metal line 14 is stressed, the stress can be better transferred to the first protective layer 12.

In summary, by synchronizing forming of the first metal line 13 and the second metal line 14, the bump 20 and the bump 21 are equivalently formed on the same layer. The coplanarity of the bumps 20 and 21 is higher, and the second metal line 14 is insulated from the pad 11, so the bump 21 on the second metal line 14 does not play a conductive role like a dummy, and the stress is transferred to the first protective layer 12 if the chip warps and generates stress. The flip-chip of the present application When the bump 21 and the bump 20 in the chip have good coplanarity, the probability of poor wetting during flip-chip package on the substrate is reduced, and the reliability of the entire package is improved.

The technical features of the above embodiments can be combined arbitrarily. To make the description concise, not all possible combinations of the technical features in the above embodiments are described. However, as long as there is no contradiction in the combination of these technical features, they should be considered as in the range described in this specification.

The exemplary embodiments of the present disclosure are specifically shown and described above. It should be understood that the present disclosure is not limited to the detailed structure, arrangement or implementation method described herein; on the contrary, the present disclosure intends to cover various modifications and equivalent arrangements included in the spirit and scope of the appended claims.

1. A semiconductor structure, comprising:
a substrate;
a pad disposed on the substrate;
a first protective layer disposed on a part of the pad;
a connecting plug, wherein the connecting plug is disposed in the first protective layer;
a redistribution layer disposed on the first protection layer, wherein the redistribution layer comprises a first metal line and a second metal line, wherein the first metal line is electrically connected to the pad via the connecting plug, wherein the second metal line is flush with an upper surface of the first metal line, and wherein the second metal line is not electrically connected to the pad;
a second protective layer disposed on an upper surface of the first protective layer and covering the redistribution layer;
a first opening and a second opening formed in the second protective layer, wherein the first opening exposes the first metal line, and the second opening exposes the second metal line; and
a first bump disposed on the upper surface of the first metal line and a second bump disposed on an upper surface of the second metal line.

2. The semiconductor structure of claim 1, further comprising a first under-bump metal layer and a second under-bump metal layer, wherein the first under-bump metal layer is disposed on an inner surface of the first opening and contacts with the first bump and the first metal line, and the second under-bump metal layer is disposed on an inner surface of the second opening and contacts with the second bump and the second metal line.

3. The semiconductor structure of claim 1, wherein a gap is configured between the second metal line and the first metal line.

4. The semiconductor structure of claim 1, wherein a width of the second opening is smaller than a width of the second metal line, and wherein a distance between an edge of the second opening and an edge of the second metal line is in the range of 2.5 um-7 um.

5. The semiconductor structure of claim 1, wherein the redistribution layer further comprises a through plug, wherein the connecting plug and the through plug both penetrate the first protection layer in a thickness direction of the first protection layer; wherein the second metal line is connected with the through plug, and wherein a width of the first metal line is greater than a width of the connecting plug and a width of the second metal line is greater than a width of the through plug.

6. The semiconductor structure of claim 1, wherein the first protective layer comprises a polymer layer and a passivation layer, wherein the passivation layer is disposed on an upper surface of the substrate, and wherein the polymer layer is disposed on an upper surface of the passivation layer.

7. A method for fabricating a semiconductor structure, comprising steps of:
providing a substrate;
forming a pad on the substrate;
disposing a first protective layer on the substrate, wherein the first protective layer covers a part of the pad;
disposing a connecting plug in the first protection layer;
disposing a redistribution layer on an upper surface of the first protection layer, wherein the redistribution layer comprises a first metal line and a second metal line, wherein the first metal line is electrically connected to the pad via the connecting plug, wherein the second metal line is flush with an upper surface of the first metal line and is not electrically connected to the pad; and
disposing a second protective layer on an upper surface of the first protective layer; forming a first opening and a second opening in the second protective layer, wherein the first opening exposes the first metal line and the second opening exposes the second metal line; and
forming a first bump on the upper surface of the first metal line and a second bump on an upper surface of the second metal line.

8. The method for fabricating the semiconductor structure of claim 7, wherein forming a first protective layer on the substrate comprises:
disposing a passivation layer on the upper surface of the substrate; and
disposing a polymer layer on the passivation layer.

9. The method for fabricating the semiconductor structure of claim 8, wherein a width of the second opening is smaller than a width of the second metal line, and wherein a distance from an edge of the second opening to an edge of the second metal line is in a range of 2.5 um˜7 um.

10. The manufacturing method according to claim 8, wherein after forming the first opening and the second opening in the second protective layer and before forming the first bump and the second bump, the method further comprises steps of:
disposing a first under-bump metal layer on an inner surface of the first opening and a second under-bump metal layer on an inner surface of the second opening, wherein the first under-bump metal layer is in contact with the first metal line, wherein the second under-bump metal layer is in contact with the second metal line; and wherein the first bump and the second bump are formed on surfaces of the first and second under-bump metal layers respectively.

11. The method for fabricating the semiconductor structure of claim 7, wherein forming a connecting plug in the first protective layer and forming the redistribution layer on the upper surface of the first protective layer comprises steps of:
forming a connecting opening in the first protection layer, wherein the connecting opening exposes the pad; and
forming the connecting plug in the connecting opening;
wherein the first metal line and the second metal line are disposed on the upper surface of the first protective layer.

12. The method for fabricating the semiconductor structure of claim 7, wherein forming the distribution layer comprises steps of:
forming a connecting opening and through openings in the first protective layer, wherein the connection opening exposes the pad; and
forming a connecting plug in the connecting opening, and forming through plugs in the through openings;
wherein the first metal line is connected to the connecting plug and a part of the through plugs; wherein the second metal line is connected to a remaining through plugs; and
wherein a width of the first metal line and a width of the second metal line are both larger than a width of the connecting plug or a width of each of the through plugs.

13. A semiconductor package structure, comprising the semiconductor structure of claim 1.

14. The semiconductor package structure of claim 13, wherein the semiconductor structure is flip-chip mounted on the substrate, wherein the first bump is attached to the substrate, wherein a plastic encapsulation layer is formed on a periphery of the semiconductor structure, and wherein the plastic encapsulation layer surrounds the first and the second bumps.
